(19) United States
(12) Patent Application Publication
(10) Pub. No.: US 2025/0343528 A1
(43) Pub. Date: Nov. 6, 2025

(54) FILM BULK ACOUSTIC WAVE RESONATOR HAVING STEEP AIR CAVITY ANGLE AND INCLUDING FILLERS DISPOSED IN THE AIR CAVITY

(71) Applicant: SKYWORKS GLOBAL PTE. LTD., Singapore (SG)

(72) Inventors: Yanbo He, Irvine, CA (US); Wan Wan, Irvine, CA (US); Kwang Jae Shin, Yongin-si (KR); Zongliang Cao, Irvine, CA (US)

(21) Appl. No.: 19/192,789

(22) Filed: Apr. 29, 2025

Related U.S. Application Data
(60) Provisional application No. 63/641,085, filed on May 1, 2024.

(51) Int. Cl. H03H 9/17

(52) U.S. Cl. CPC H03H 9/173

(57) ABSTRACT

Aspects and embodiments disclosed herein include a film bulk acoustic wave resonator comprising a layer of piezoelectric material disposed between a top electrode and a bottom electrode, a central active region and a raised frame region defined around the central active region, an air cavity defined below the bottom electrode in each of the central active region and raised frame region, the air cavity having a sidewall with an air cavity sidewall angle of between 60° and 90°, and at least one filler disposed within the air cavity and extending from the sidewall inward toward the central active region.

### CROSS-REFERENCE TO RELATED APPLICATIONS

This application claims priority under 35 U.S.C. § 119 (e) to U.S. Provisional Patent Application Ser. No. 63/641,085, titled “FILM BULK ACOUSTIC WAVE RESONATOR HAVING STEEP AIR CAVITY ANGLE AND INCLUDING FILLERS DISPOSED IN THE AIR CAVITY,” filed May 1, 2024, the entire content of which is incorporated herein by reference for all purposes.

### TECHNICAL FIELD

Embodiments of this disclosure relate to bulk acoustic wave resonators and to acoustic wave filters including same in which the bulk acoustic wave resonators exhibit a combination of enhanced quality factor and reduced piezoelectric material layer stress concentrations.

### Description of Related Technology

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a film bulk acoustic wave resonator. The film bulk acoustic wave resonator comprises a layer of piezoelectric material disposed between a top electrode and a bottom electrode, a central active region and a raised frame region defined around the central active region, an air cavity defined below the bottom electrode in each of the central active region and raised frame region, the air cavity having a sidewall with an air cavity sidewall angle of between 60° and 90°, and at least one filler disposed within the air cavity and extending from the sidewall inward toward the central active region.

In some embodiments, the at least one filler has a length of between 1 μm and 2 μm.

In some embodiments, the at least one filler extends vertically from a floor to a roof of the air cavity.

In some embodiments, the at least one filler is a single filler formed of a single material.

In some embodiments, the single filler does not extend inwardly toward the central active region past an outer edge of the bottom electrode.

In some embodiments, the single filler extends inwardly toward the central active region past an outer edge of the bottom electrode.

In some embodiments, the single filler does not extend inwardly toward the central active region past an inner edge of the raised frame region.

In some embodiments, the at least one filler includes a first filler formed of a first material and a second filler formed of a second material.

In some embodiments, the first filler is formed of polysilicon and the second filler is formed of AlN.

In some embodiments, the first filler is formed of polysilicon and the second filler is formed of SiO₂.

In some embodiments, the first filler is formed of air and the second filler is formed of AlN.

In some embodiments, the first filler is formed of air and the second filler is formed of SiO₂.

In some embodiments, the first filler is disposed against the sidewall and the second filler is disposed on a side of the first filler opposite the sidewall.

In some embodiments, the first filler does not extend inwardly toward the central active region past an outer edge of the bottom electrode.

In some embodiments, the first filler extends inwardly toward the central active region past an outer edge of the bottom electrode.

In some embodiments, the second filler extends inwardly toward the central active region past an outer edge of the bottom electrode.

In some embodiments, the second filler is disposed entirely beneath the bottom electrode.

In some embodiments, the film bulk acoustic wave resonator is included in a radio frequency filter.

In some embodiments, the radio frequency filter is configured as a ladder filter.

In some embodiments, the radio frequency filter is included in a radio frequency module.

In some embodiments, the radio frequency module is included in a radio frequency device.

In accordance with another aspect, there is provided a method of reducing stress in a layer of piezoelectric material of a film bulk acoustic wave resonator having a top electrode and a bottom electrode sandwiching the layer of piezoelectric material, a central active region and a raised frame region defined around the central active region, and an air cavity defined below the bottom electrode in each of the central active region and raised frame region, the air cavity having a sidewall with an air cavity sidewall angle of between 60° and 90°. The method comprises disposing at least one filler within the air cavity and extending from the sidewall inward toward the central active region.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 illustrates examples of film bulk acoustic wave resonators having different air cavity sidewall angles;

FIG. 3A illustrates a distribution of stress in a layer of piezoelectric material in a conventional film bulk acoustic wave resonator;

FIG. 3B illustrates distributions of stress in layers of piezoelectric material in examples of film bulk acoustic wave resonators;

FIG. 3C illustrates distributions of stress in layers of piezoelectric material in further examples of film bulk acoustic wave resonators;

FIGS. 4A-4G illustrate portions of further examples of film bulk acoustic wave resonators;

FIGS. 5A-5C illustrate portions of further examples of film bulk acoustic wave resonators;

FIG. 6 illustrates a simplified schematic diagram of a ladder filter that may be formed from resonators as disclosed herein;

FIG. 7 illustrates an embodiment of an electronics module;

FIG. 8 illustrates an example of a front-end module which may be used in an electronic device; and

FIG. 9 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

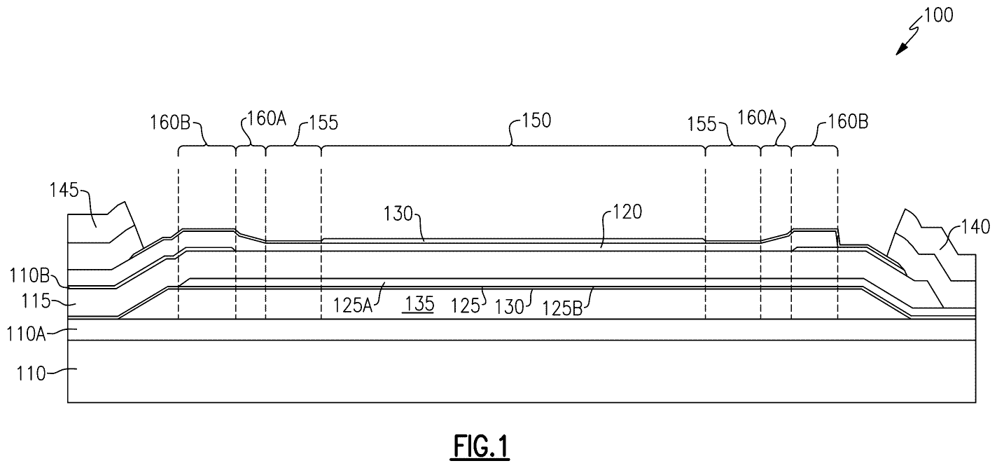

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AIN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. An air cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 (also referred to as a central active region) including a main active domain in the layer or film of piezoelectric material 115 in which a main acoustic wave is excited during operation. The central region may have a width of, for example, between about 20 μm and about 100 μm. A recessed frame region or regions 155 may be disposed around, bound, and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150, or in other embodiments a thinner portion of the top electrode 120 than the portion of the top electrode in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 130 in the recessed frame region(s) 155 is typically etched during manufacturing to achieve a desired difference in acoustic velocity between the central region 150 and the recessed frame region(s) 155. Accordingly, the dielectric film 130 initially deposited in both the central region 150 and recessed frame region(s) 155 is deposited with a sufficient thickness that allows for etching of sufficient dielectric film 130 in the recessed frame region(s) 155 to achieve a desired difference in thickness of the dielectric film 130 in the central region 150 and recessed frame region(s) 155 to achieve a desired acoustic velocity difference between these regions.

A metal raised frame region or regions 160A and an oxide raised frame region or regions 160B (collectively, raised frame region or regions 160) may be defined around the central region 150 on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The oxide raised frame region(s) 160B may additionally include a layer of silicon dioxide 110B between the top electrode and the layer or film of piezoelectric material 115. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

One important operating parameter for a BAW resonator is quality factor Q, which may be considered as the amount of input energy that is stored or converted to desired acoustic waves within the resonator rather than lost due to, for example, electrical or acoustic wave energy leakage from the active region of the resonator.

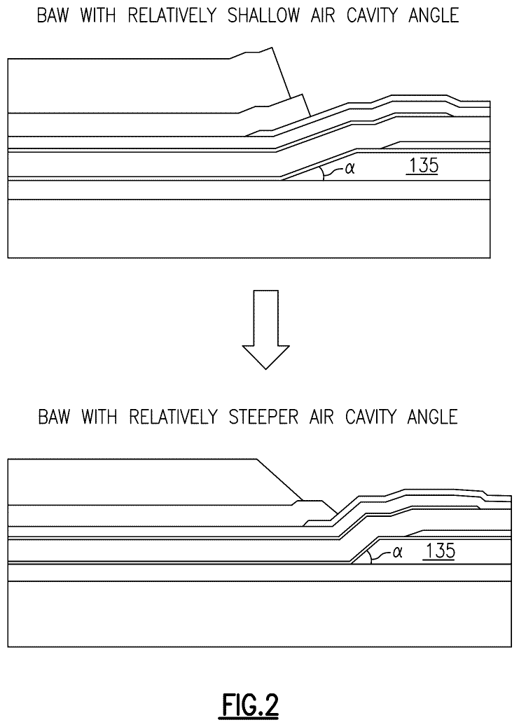

It has been discovered that the angle of the sidewall of the air cavity 135 of a BAW resonator has an effect on the quality factor exhibited by the resonator. The angle of the sidewall of the air cavity 135 is defined herein as the angle between a sidewall of the air cavity 135 and the floor of the air cavity 135. Generally, a higher air cavity sidewall angle results in a BAW resonator with a higher quality factor than a similar BAW resonator with a shallower air cavity sidewall angle. In some prior art designs, the air cavity sidewall angle of a BAW resonator was set at about 19°. It has been discovered that a significant increase in quality factor may be obtained by increasing the air cavity sidewall angle to 45° or greater, for example, between about 45° and about 90°, between about 60° and about 90°, or between about 70° and about 80°, however, embodiments disclosed herein may have an air cavity sidewall angle ranging anywhere from 20° to 90°. FIG. 2 illustrates portions of two BAW resonators on the side of the resonator having the electrical contact with the top electrode with different air cavity sidewall angles α. The configuration of the portions of the resonators shown in FIG. 2 are slightly different than the example shown in FIG. 1.

When the air cavity sidewall angle of a BAW resonator is changed, this also changes the shape of the layer of piezoelectric material overlying the air cavity sidewalls. An increase in the change in angle of the layer of piezoelectric material to conform to the increased air cavity sidewall angle may introduce stresses into the layer of piezoelectric material above the edges of the air cavity that may potentially lead to a reduction in resonator ruggedness or reliability, for example, to cracking of the layer of piezoelectric material. To alleviate the increased stresses in the layer of piezoelectric material above the edges of the air cavity one may dispose filler material into the air cavity at or proximate the edge of the air cavity. In various embodiments, the filler material may include a dielectric (e.g., SiO₂, SiC, Si₃N₄, A1₂O₃, BeO₂, etc.), a metal (e.g., Mo, W, Ru, Al, Cu, Au etc.), a piezoelectric material (e.g., AlN, ZnO, LiNbO₃, LiTaO₃, etc.), or combinations of these types of materials. In some examples, selecting a filler with a high thermal conductivity may contribute to superior heat dissipation in the BAW resonator.

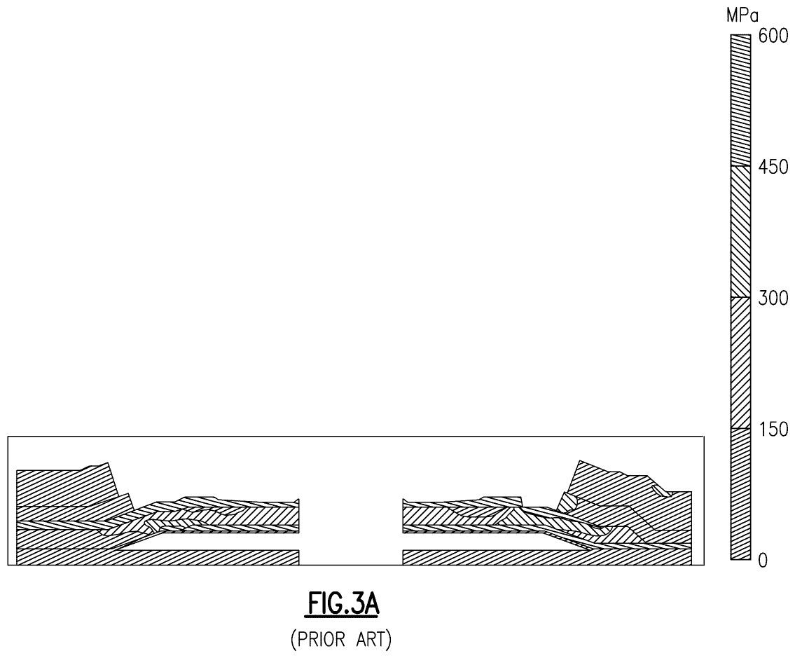

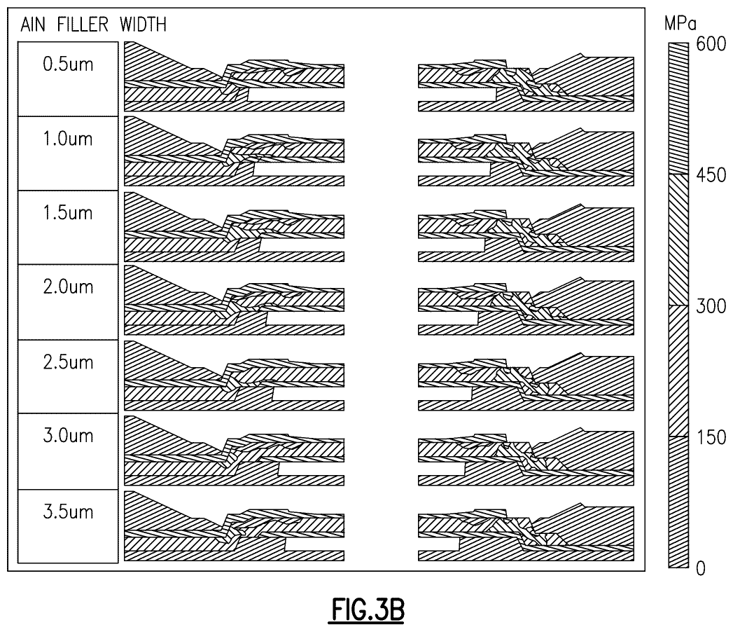

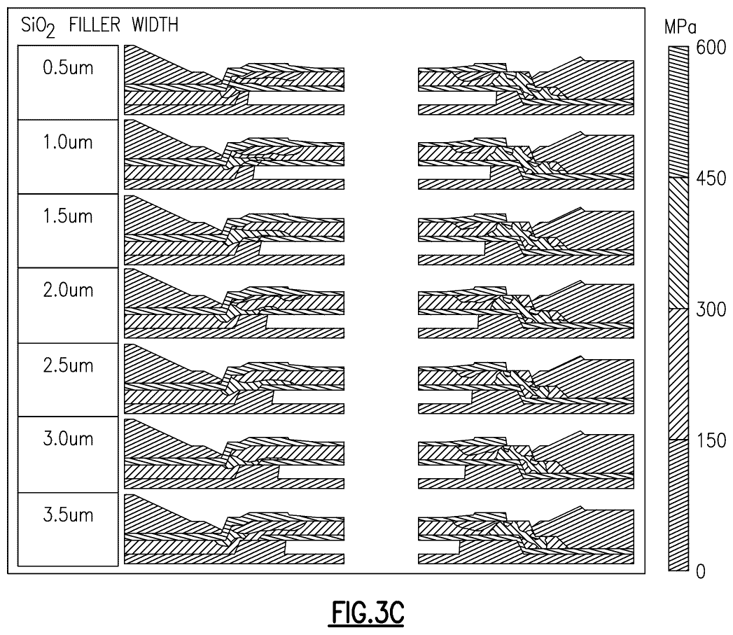

FIG. 3A illustrates results of a simulation of stresses that may be observed in the layer of piezoelectric material in a BAW resonator with a relatively shallow air cavity sidewall angle where no filler material is present in the air cavity. FIG. 3B illustrates results of simulations of how increased stresses in the layer of piezoelectric material in a BAW resonator with a relatively steep air cavity sidewall angle of 70° may be alleviated by adding AIN filler material into the air cavity extending from the air cavity sidewall by various lengths. FIG. 3C illustrates results of simulations of how increased stresses in the layer of piezoelectric material in a BAW resonator with a relatively steep air cavity sidewall angle of 70° may be alleviated by adding SiO₂ filler material into the air cavity extending from the air cavity sidewall by various lengths. The majority of the additional stresses in the layer of piezoelectric material caused by increasing the air cavity sidewall angle to 70° may be alleviated by adding the filler material into the air cavity and extending from the air cavity edges by about 1.5 μm.

Adding filler material into the air cavity of a BAW resonator may partially constrain vibration of the layer of piezoelectric material and may lead to a decrease in resonator quality factor. A simulation was performed to determine how quality factor, specifically quality factor at the anti-resonance frequency Qₚ of a BAW resonator with a steep air cavity sidewall angle as disclosed herein, changed with change in length of extension of the filler material from the air cavity edge into the air cavity and with changes in width of the raised frame regions. It was observed that the Qₚ of the resonator remained within an acceptable range for various raised frame widths when the filler material extended into the air cavity by up to about 2 μm. These results, combined with the results of the simulation of piezoelectric material layer stress indicate that a length of filler material extension from the air cavity sidewall into the air cavity of from 1 μm to 2 μm or from 1.5 μm to 2 μm may provide a good amount of piezoelectric material layer stress alleviation while maintaining an acceptable Qₚ as well as an acceptable quality factor at the series resonance frequency (Qₛ) of the BAW resonator.

As noted above, one or more different materials may be utilized as filler materials to include within the air gap of a BAW resonator with steep air cavity sidewall angles as disclosed herein. Some examples may include two different filler materials, with the filler at or closest to the air cavity edge being referred to as a first filler herein and a filler more distal from the air cavity edge than the first filler being referred to a second filler herein. In different embodiments, the first and second fillers may have either the same or different widths, but will generally extend from the floor of the air cavity to the roof of the air cavity 135 (or from the floor to the sidewall of the air cavity for portions disposed in areas beneath a slanted sidewall of the air cavity 135).

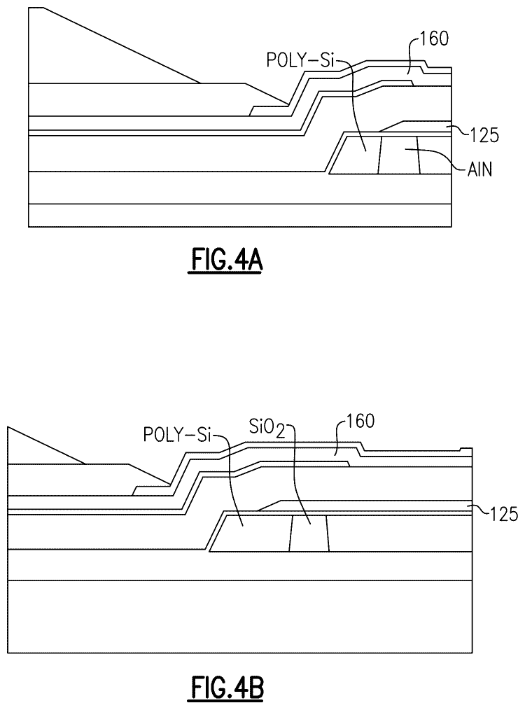

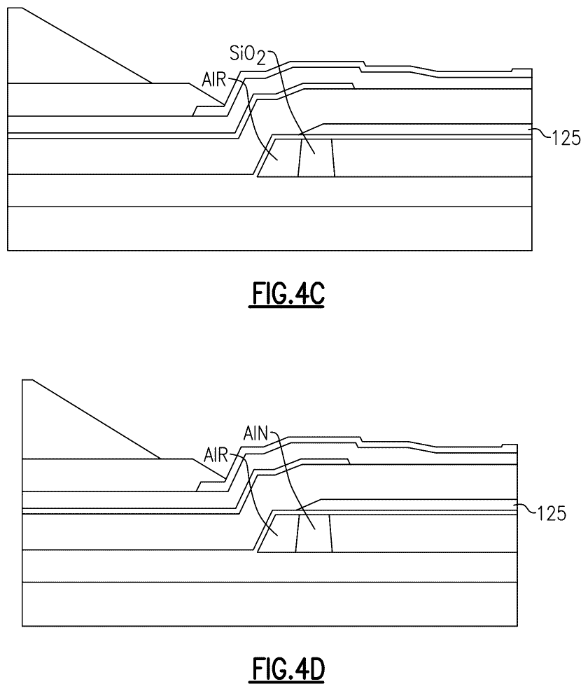

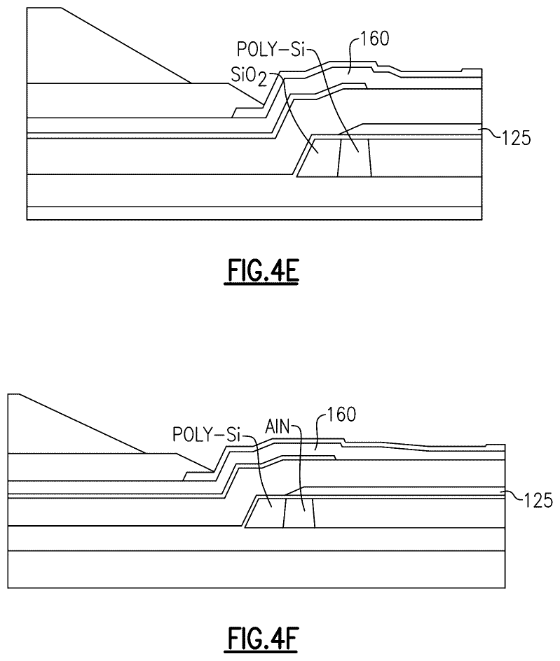

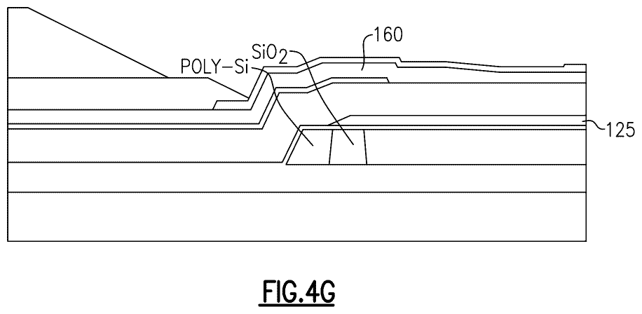

FIG. 4A illustrates an example in which the material of the first filler is polysilicon and a second filler formed of AlN directly abuts the inner side of the first filler. The interface between the polysilicon and the AlN is substantially aligned with an edge of the lower electrode 125 and the inner side of the AlN is substantially aligned with the inner edge of the raised frame 160. FIG. 4B illustrates an example in which the material of the first filler is polysilicon and a second filler formed of SiO₂ directly abuts the inner side of the polysilicon filler. The interface between the SiO₂ and the polysilicon is below a point on the lower electrode 125 distal from the end of the inner electrode 125. The raised frame 160 extends further inward than the combination of the first and second fillers. FIG. 4C illustrates another configuration of filler in which there is no first filler, but only a second filler formed of SiO₂ with an outer edge aligned with the edge of the lower electrode 125 and an air gap defined between the outer edge of the SiO₂ filler and the sidewall of the air cavity. In an alternate interpretation the air within the air gap may be considered the first filler and the SiO₂ may be considered the second filler. A configuration is illustrated in FIG. 4D in which the first filler is air, the second filler is AlN, and an outer edge of the AlN filler is aligned with the edge of the lower electrode 125. FIG. 4E illustrates a configuration in which the material of the first filler is SiO₂ and the material of the second filler is polysilicon. FIG. 4F illustrates another filler configuration with a first filler formed of polysilicon and a second filler formed of AlN. The interface between the first and second fillers are aligned beneath the edge of the bottom electrode 125 and the raised frame 160 extends further inward over the air cavity than the fillers. FIG. 4G illustrates a similar structure as FIG. 4F, but utilizes a polysilicon first filler and a SiO₂ second filler. It was observed that embodiments with first and second fillers formed of SiO₂ and polysilicon gave slightly better Qₚresults than embodiments with first and second fillers formed of AlN and polysilicon. Embodiments with wider raised frames also exhibited higher Qₚ values than embodiments with narrower raised frame for a given filler or combination of fillers.

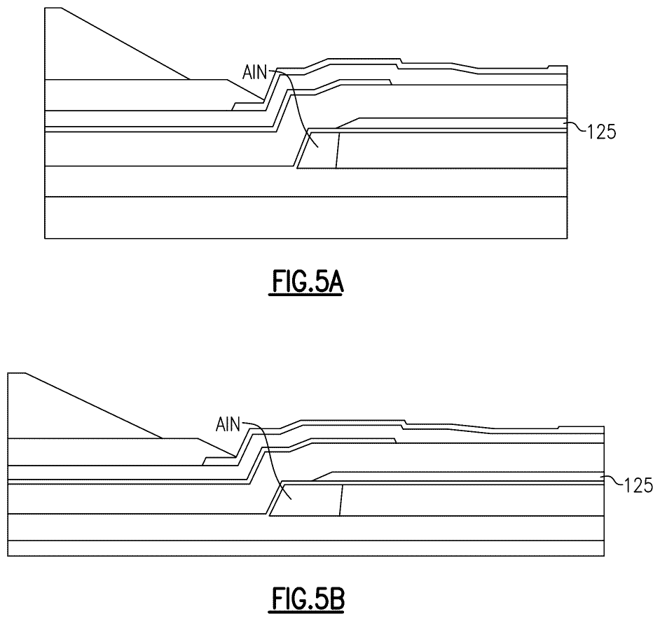

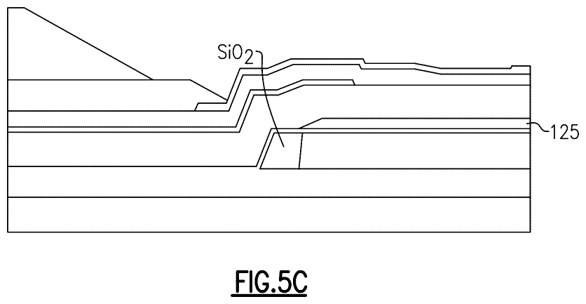

In further embodiments, there may be a first filler, but no second filler. For example, FIG. 5A shows a configuration with an AlN filler that has an outer side abutting the air cavity sidewall and an inner side aligned with the edge of the lower electrode 125, although in other embodiments, the filler may extend inward beyond the edge of the lower electrode as shown, for example, in FIG. 5B. FIG. 5C shows a similar configuration as FIG. 5A, but utilizes a SiO₂ filler rather than an AlN filler.

The acoustic wave devices discussed herein can be implemented in a variety of filters and packaged modules. Some example packaged modules will now be discussed in which any suitable principles and advantages of the packaged acoustic wave devices discussed herein can be implemented. FIGS. 6, 7, 8, and 9 are schematic block diagrams of an illustrative filter and packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example.

In some embodiments, multiple BAW resonators as disclosed herein may be combined into a filter, for example, an RF ladder filter schematically illustrated in FIG. 6 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

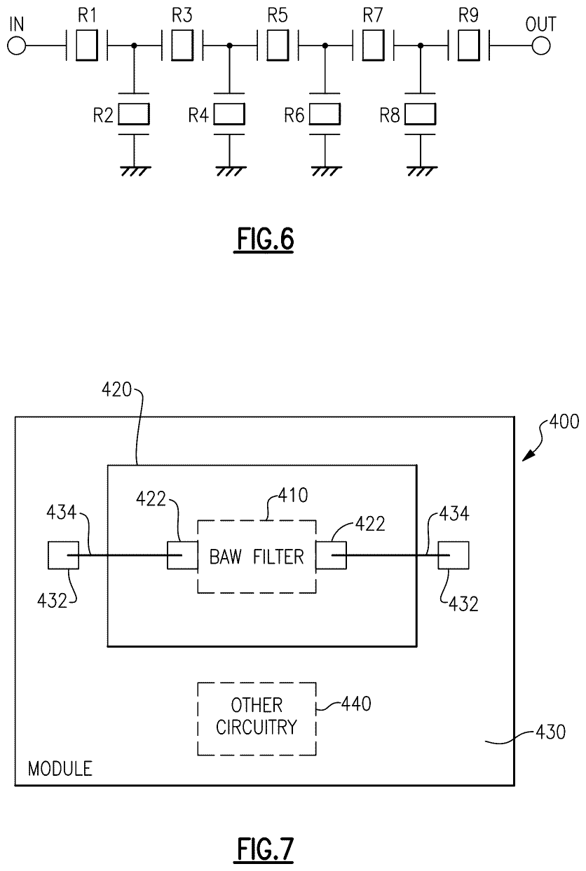

FIG. 7 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

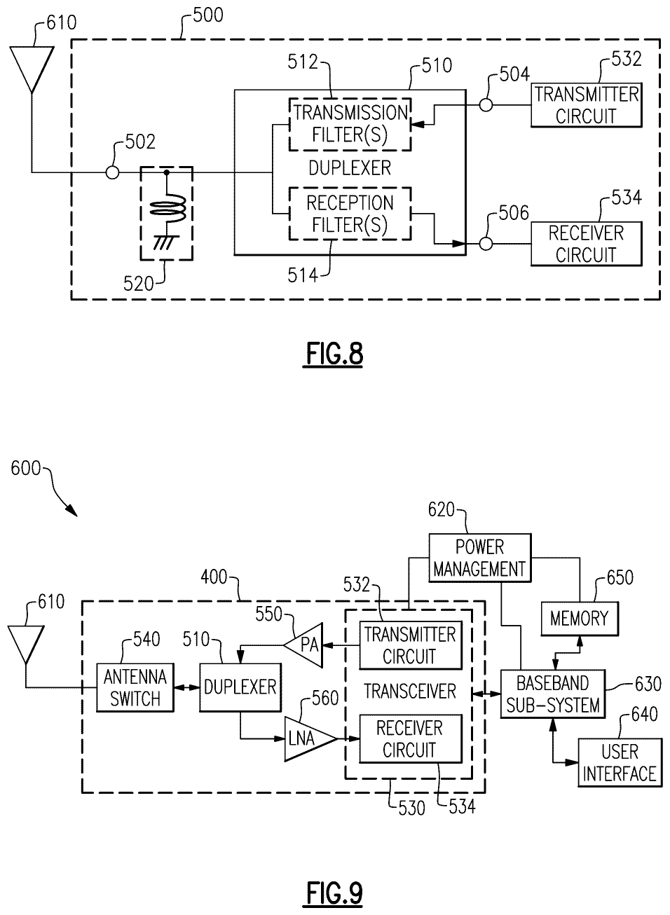

Referring to FIG. 8, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 8, however in other embodiments these components may be integrated into a common transceiver circuit or module. As will be appreciated by those skilled in the art, the front-end module 500 may include other components that are not illustrated in FIG. 8 including, but not limited to, switches, electromagnetic couplers, amplifiers, processors, and the like.

FIG. 9 is a block diagram of one example of a wireless device 600 including the antenna duplexer 510 shown in FIG. 8. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 8. The front-end module 500 includes the duplexer 510, as discussed above. In the example shown in FIG. 9 the front-end module 500 further includes an antenna switch 540, which can be configured to switch between different frequency bands or modes, such as transmit and receive modes, for example. In the example illustrated in FIG. 9, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 8.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 9, the front-end module 500 may further include a low noise amplifier module 560, which amplifies received signals from the antenna 610 and provides the amplified signals to the receiver circuit 534 of the transceiver 530.

The wireless device 600 of FIG. 9 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above

Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A film bulk acoustic wave resonator comprising:
a layer of piezoelectric material disposed between a top electrode and a bottom electrode;
a central active region and a raised frame region defined around the central active region;
an air cavity defined below the bottom electrode in each of the central active region and raised frame region, the air cavity having a sidewall with an air cavity sidewall angle of between 60° and 90°; and
at least one filler disposed within the air cavity and extending from the sidewall inward toward the central active region.

2. The film bulk acoustic wave resonator of claim 1 wherein the at least one filler has a length of between 1 μm and 2 μm.

3. The film bulk acoustic wave resonator of claim 1 wherein the at least one filler extends vertically from a floor to a roof of the air cavity.

4. The film bulk acoustic wave resonator of claim 1 wherein the at least one filler is a single filler formed of a single material.

5. The film bulk acoustic wave resonator of claim 4 wherein the single filler does not extend inwardly toward the central active region past an outer edge of the bottom electrode.

6. The film bulk acoustic wave resonator of claim 4 wherein the single filler extends inwardly toward the central active region past an outer edge of the bottom electrode.

7. The film bulk acoustic wave resonator of claim 4 wherein the single filler does not extend inwardly toward the central active region past an inner edge of the raised frame region.

8. The film bulk acoustic wave resonator of claim 1 wherein the at least one filler includes a first filler formed of a first material and a second filler formed of a second material.

9. The film bulk acoustic wave resonator of claim 8 wherein the first filler is formed of polysilicon and the second filler is formed of one of AlN or SiO₂.

10. The film bulk acoustic wave resonator of claim 8 wherein the first filler is formed of air and the second filler is formed of one of AlN or SiO₂.

11. The film bulk acoustic wave resonator of claim 8 wherein the first filler is disposed against the sidewall and the second filler is disposed on a side of the first filler opposite the sidewall.

12. The film bulk acoustic wave resonator of claim 11 wherein the first filler does not extend inwardly toward the central active region past an outer edge of the bottom electrode.

13. The film bulk acoustic wave resonator of claim 11 wherein the first filler extends inwardly toward the central active region past an outer edge of the bottom electrode.

14. The film bulk acoustic wave resonator of claim 11 wherein the first filler extends inwardly toward the central active region past an outer edge of the bottom electrode.

15. The film bulk acoustic wave resonator of claim 11 wherein the second filler extends inwardly toward the central active region past an outer edge of the bottom electrode.

16. The film bulk acoustic wave resonator of claim 11 wherein the second filler is disposed entirely beneath the bottom electrode.

17. A radio frequency filter including the film bulk acoustic wave resonator of claim 1.

18. A radio frequency module including the radio frequency filter of claim 17.

19. A radio frequency device including the radio frequency module of claim 18.

20. A method of reducing stress in a layer of piezoelectric material of a film bulk acoustic wave resonator having a top electrode and a bottom electrode sandwiching the layer of piezoelectric material, a central active region and a raised frame region defined around the central active region, and an air cavity defined below the bottom electrode in each of the central active region and raised frame region, the air cavity having a sidewall with an air cavity sidewall angle of between 60° and 90°, the method comprising disposing at least one filler within the air cavity and extending from the sidewall inward toward the central active region.
